(19) United States
(12) Patent Application Publication
(10) Pub. No.: US 2011/0100421 A1
(43) Pub. Date: May 5, 2011

(54) PHOTOVOLTAIC MODULE, PHOTOVOLTAIC MODULE MOUNTING SUPPORT STRUCTURE, AND PHOTOVOLTAIC MODULE INSTALLATION METHOD

(75) Inventor: Hiroko Murayama, Hashima-city (JP)

(73) Assignee: SANYO ELECTRIC CO., LTD., Moriguchi-shi (JP)

(21) Appl. No.: 12/911,097

(22) Filed: Oct. 25, 2010

(30) Foreign Application Priority Data
Oct. 30, 2009 (JP) 2009-251326
Oct. 8, 2010 (JP) 2010-228345

(51) Int. Cl. H01L 31/042; B23P 11/00; H05K 7/14

(52) U.S. Cl. 136/246; 29/428; 248/636

(57) ABSTRACT

To provide an installation method for installing a photovoltaic module comprising a photovoltaic module, a support structure for supporting the photovoltaic module mounted thereon, a fixing member for fixing the photovoltaic module to the support structure; and a damper placed between a rear surface of the photovoltaic module and a surface of the support structure when the photovoltaic module is fixed to the support structure, using the fixing member.

### CROSS-REFERENCE TO RELATED APPLICATIONS

The entire disclosure of Japanese Patent Applications No. 2009-251326 filed on Oct. 30, 2009 and 2010-228345 filed on Oct. 8, 2010, including specification, claims, drawings, and abstract, is incorporated herein by reference in its entirety.

### BACKGROUND OF THE INVENTION

1. Field of the Invention

The present invention relates to a photovoltaic module, a photovoltaic module mounting support structure, and a photovoltaic module installation method.

2. Description of the Related Art

Photovoltaic systems, such as solar power generation systems, or the like, are generally formed as photovoltaic modules comprising a plurality of photovoltaic cells connected in series-parallel and sealed with filler or the like, and an integrally formed structural body, such as a metallic frame, or the like. A photovoltaic system is installed by mounting the photovoltaic module on a support structure placed in an installation position.

For example, there is disclosed a photovoltaic module formed by attaching a structural member to a photovoltaic panel so as to be integral, the photovoltaic panel having photovoltaic cells arranged between a light transmitting substrate and a rear surface member. The structural member of such a photovoltaic module is adapted to integral connection to at least a structural member of another photovoltaic module. Therefore, with an arrangement in which a support structure structural member is integrally assembled to a photovoltaic panel in advance, the photovoltaic module can be readily installed in an installation position by simply connecting the structural members of adjacent photovoltaic modules.

Here, as shown in the cross sectional view in FIG. 5, a conventional photovoltaic module has a structure for installation, in which a structural member 12 provided on an edge part of the photovoltaic module 10 is fixed to the support structure 14 so that the photovoltaic module 10 is supported on the edge parts thereof.

In such a case, a damper 16, such as rubber or the like, is provided between the support structure 14 and the photovoltaic module 10, as shown in FIG. 5. As a result, a space is caused between the support structure 14 and the rear surface of the photovoltaic module 10. Moreover, as the support structure 14 or the like does not have a shock-resistive structure, the photovoltaic module 10 may possibly be deformed at the time of or after installation. As a result, the photovoltaic module 10 may be caused to directly contact the support structure 14, which may damage the photovoltaic module 10.

### SUMMARY OF THE INVENTION

According to one aspect of the present invention, there is provided an installation structure for installing a photovoltaic module comprising a photovoltaic panel; a support structure for supporting the photovoltaic module mounted thereon; a fixing member for fixing the photovoltaic module to the support structure; and a damper placed between a rear surface of the photovoltaic module and a surface of the support structure when the photovoltaic module is fixed to the support structure, using the fixing member.

### BRIEF DESCRIPTION OF THE DRAWINGS

FIG. 1 is a plan view showing a structure for a photovoltaic module installation method according to an embodiment of the present invention;

FIG. 2 is a cross sectional view showing a structure for a photovoltaic module installation method according to the embodiment of the present invention;

FIG. 3 is a plan view showing another example of a structure for a photovoltaic module installation method according to the embodiment of the present invention;

FIG. 4 is a cross sectional view showing another example of a structure for a photovoltaic module installation method according to the embodiment of the present invention;

FIG. 5 is a cross sectional view showing a structure for a photovoltaic module installation method according to related art;

FIG. 6 is a plan view showing another example of a structure for a photovoltaic module installation method according to the embodiment of the present invention; and

FIG. 7 is a cross sectional view showing another example of a structure for a photovoltaic module installation method according to the embodiment of the present invention.

### DESCRIPTION OF THE PREFERRED EMBODIMENTS

As shown in the plan view in FIG. 1, an installation method for installing a photovoltaic module according to an embodiment of the present invention is carried out using a photovoltaic module 100, a mounting support structure 102, and a damper 104. FIG. 1 is a plan view of photovoltaic modules 100 mounted and viewed from the rear surface side thereof.

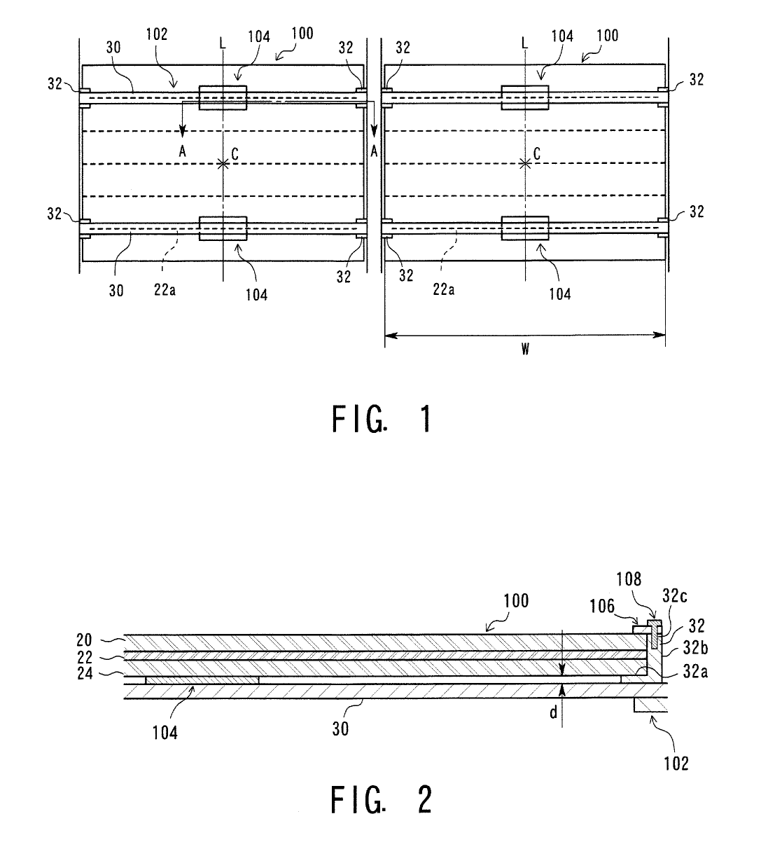

As shown in the cross sectional view in FIG. 2, the photovoltaic module 100 comprises a front side substrate 20, a photovoltaic cell 22, and a rear side substrate 24. Note that FIG. 2 is a cross sectional view along the line A-A in FIG. 1.

The front side substrate 20 is a member for supporting the photovoltaic cell 22 on the front surface side thereof. The front side substrate 20 is made using light-transmitting material, such as, e.g., glass, plastic, and the like, so as to guide incident light to the photovoltaic cell 22.

The rear side substrate 24 is a member for supporting the photovoltaic cell 22 on the rear surface side thereof. For a photovoltaic module 100 capable of receiving light from both of the front and rear surfaces thereof, the rear side substrate 24 is also made using light-transmitting material, such as, e.g., glass, plastic, and the like. Meanwhile, for a photovoltaic module 100 capable of receiving light only from the front surface thereof, the rear side substrate 24 may be made using material which does not pass light, such as metal, cured filler, including EVA etc., or the like.

The photovoltaic cell 22 has a laminated structure including a transparent electrically conductive layer and a photovoltaic layer. A transparent electrically conductive oxide (TCO) formed by doping tin (Sn), antimony (Sb), fluorine (F), aluminum (Al), or the like to stannous oxide (SnO₂), zinc oxide (ZnO), indium tin oxide (ITO), or the like can be used. The photovoltaic layer is formed on the transparent electrically conductive layer. As a photovoltaic layer, for example, an amorphous silicon photovoltaic layer, a microcrystal silicon photovoltaic layer, and a tandem structure thereof, and a compound semiconductor photovoltaic layer, such as a gallium arsenide base or the like, can be used. In a case of using an amorphous silicon photovoltaic layer or a microcrystal silicon photovoltaic layer, preferably, a PN-type photovoltaic layer including p-type and n-type semiconductor layers laminated, or a PIN-type photovoltaic layer including p-type, i-type and n-type semiconductors laminated, may be employed.

As shown in FIG. 1, the photovoltaic cell 22 may have a structure in which the transparent electrically conductive layer and the photovoltaic layer are divided by a separating groove 22a formed using laser beam or the like such that a plurality of photovoltaic cells are connected in series or in parallel. As a laser beam, for example, a YAG laser having wavelengths of 1064 nm and 532 nm may be used.

For a photovoltaic module 100 capable of receiving light from both of the front and rear surfaces thereof, the photovoltaic cell 22 may be formed on each of the front side substrate 20 and the rear side substrate 24 so that the photovoltaic cells 22 are connected to each other with the inter layer consisting of the transparent electrically conductive layer, the metal layer, or the like, in-between.

Meanwhile, for a photovoltaic module 100 capable of receiving light from only from the front surface, the photovoltaic cell 22 is formed on the front side substrate 20, on which rear electrodes, resin, and the like are provided, with the rear side substrate 24 further placed thereon. Preferably, the rear electrode has a laminated structure including, e.g., reflective metal and transparent electrically conductive oxide (TCO). As reflective metal, silver (Ag), aluminum (Al), and the like are available. As transparent electrically conductive oxide (TCO), stannous oxide (SnO₂), zinc oxide (ZnO), indium tin oxide (ITO), and the like, are available. As resin, resin material, such as EVA or the like, may be preferably used.

The mounting support structure 102 comprises a support structure 30 and a fixing member 32. The support structure 30 is a structural member mounted on the mounting support structure 102, for supporting the photovoltaic module 100. The fixing member 32 is a member mounted on the support structure 30, for fixing the photovoltaic module 100 to the support structure 30.

As shown in FIG. 1, preferably, the support structure 30 has a bar shape on which a plurality of photovoltaic modules 100 can be mounted side by side, though the present invention is not limited to this shape. That is, the support structure 30 may have any other shape, including a flat panel, or the like, as long as the shape can support the photovoltaic module 100 on the rear surface side thereof.

The support structure 30 is made using material having mechanical strength sufficient to mount and support the photovoltaic module 100. The support structure 30 can be made using metal, reinforced plastic, and the like. Preferably, the support structure 30 is made using, for example, an aluminum member.

In a case where the separating groove 22a is formed on the photovoltaic cell 22 of the photovoltaic module 100, preferably, the support structure 30 is mounted along and overlapping the separating groove 22a. With the above, the light having passed through the photovoltaic module 100 via the separating groove 22a is reflected by the support structure 30 so that the light is introduced again to the photovoltaic cell 22, which improves photovoltaic efficiency of the photovoltaic module 100. Therefore, preferably, the support structure 30 is made using highly light reflective material or material of highly light reflective color. For example, preferably, the support structure 30 may be made using metal with a high reflective rate, such as aluminum, or the like. In addition, preferably, the support structure 30 may be colored white or the like as the color white has a high reflective rate.

As shown in the cross sectional view in FIG. 2, the fixing member 32 is fixed to the support structure 30, and used to fix the photovoltaic module 100 to the support structure 30. The fixing member 32 comprises a bottom portion 32a where the photovoltaic module 100 is to be placed, and a side portion 32b standing from the bottom portion 32a relative to the support structure 30. The fixing members 32 are arranged such that the distance between the inner wall surfaces of the side portions 32b thereof results in a portion wider than the width W between the opposed edge parts of the panel of the photovoltaic module 100. With this arrangement, in mounting the photovoltaic module 100, the position of the edge part of the panel of the photovoltaic module 100 is defined by the inner wall surface of the side portion 32b. A tap hole 32c is formed on the side portion 32b, for fixing the fixing member 106 using the bolt 108 or the like, the fixing member 106 pressing the edge part of the photovoltaic module 100 from the front surface side.

The fixing member 32 is made using material having mechanical strength sufficient to mount and support the photovoltaic module 100. The fixing member 32 can be made using metal, reinforced plastic, or the like. Preferably, the fixing member 32 is made using, for example, aluminum member.

Preferably, a damper is provided on the top surface of the bottom portion 32a and the inner wall surface of the side portion 32b, with these surfaces contacting the photovoltaic module 100. A damper may be made using an elastic member such as silicon, rubber, and the like. With a damper provided on a part which is to contact the photovoltaic module 100, the photovoltaic module 100 is prevented from receiving excessive mechanical impact when being mounted on the mounting support structure 102. Moreover, even after installation, the photovoltaic module 100 is protected from the influence of wind or the like so that no excessive stress is applied between the photovoltaic module 100 and the mounting support structure 102. This can reduce damage on the photovoltaic module 100.

Furthermore, the damper 104 is provided between the rear side substrate 24 of the photovoltaic module 100 and a surface of the support structure 30, the surface facing the rear side substrate 24 when the photovoltaic module 100 is fixed to the mounting support structure 102. With the damper 104 provided, the photovoltaic module 100 is prevented from directly contacting the support structure 30, which can reduce damage on the photovoltaic module 100. The damper 104 can be made using an elastic member such as silicon, rubber, and the like.

As shown in FIGS. 1 and 2, the damper 104 can be provided partially in the space between the rear side substrate 24 of the photovoltaic module 100 and the surface of the support structure 30. The photovoltaic module 100 is supported by the support structure 30 with the fixing member 32 as a fulcrum, and tends to flex due to its own weight or the like in a point symmetrical manner relative to the center of gravity C of the panel of the photovoltaic module 100. Therefore, preferably, the damper 104 is arranged in the space between the rear side substrate 24 of the photovoltaic module 100 and the surface of the support structure 30 so as to be point symmetrical relative to the center of gravity C of the panel of the photovoltaic module 100.

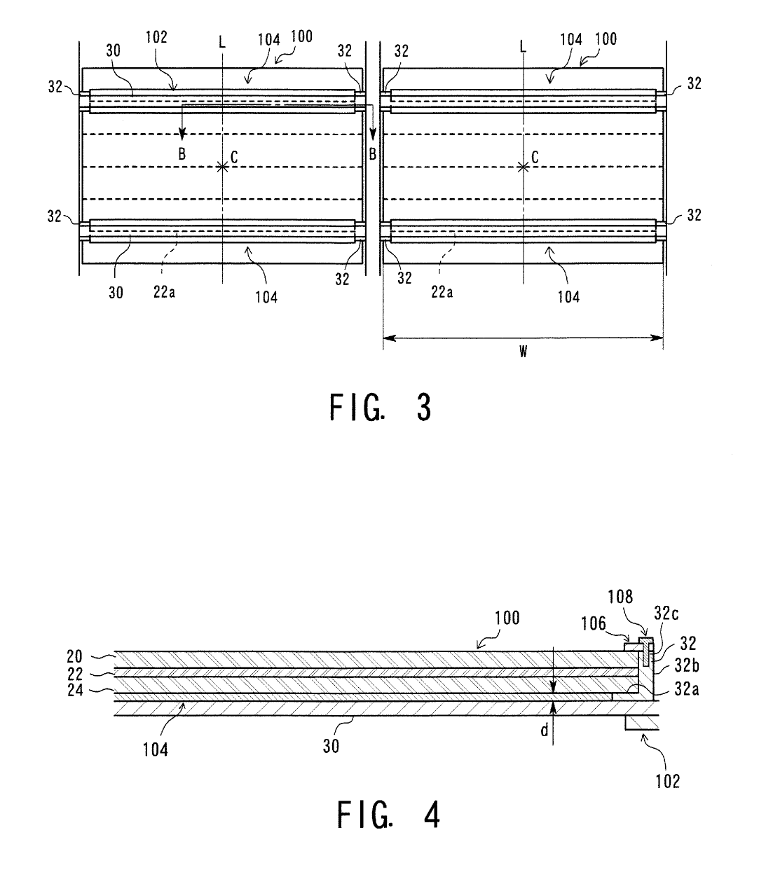

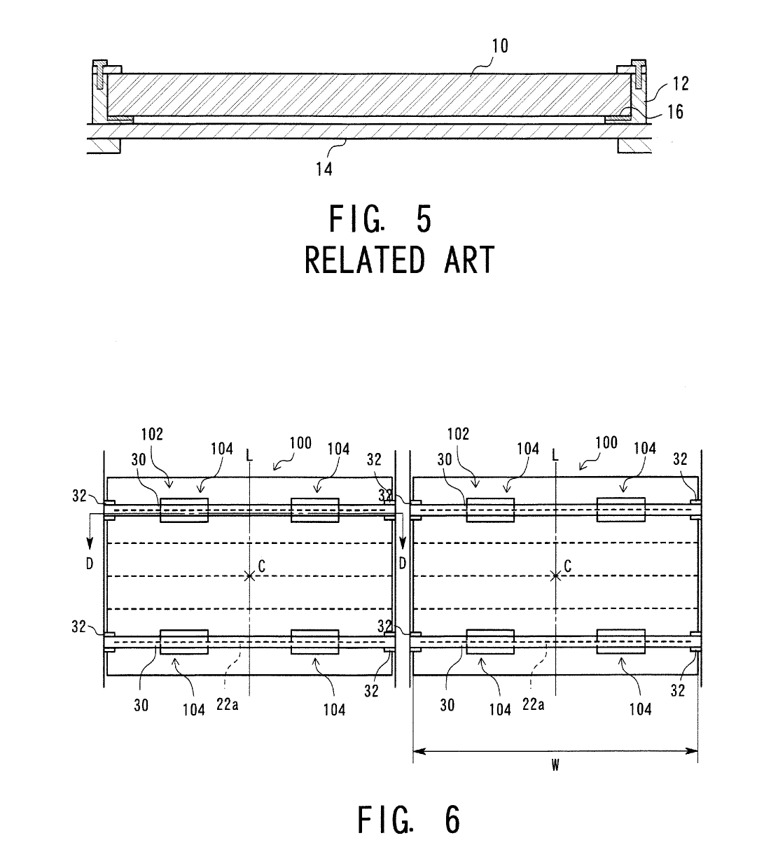

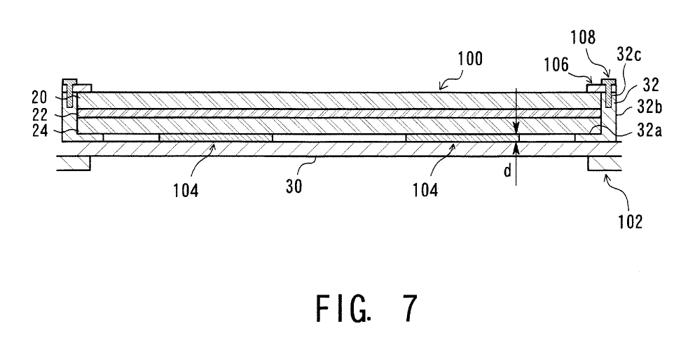

For example, as shown in FIGS. 1 and 3, preferably, the damper 104 is provided near the middle of the space between the photovoltaic module 100 and the support structure 30. Alternatively, as shown in FIGS. 6 and 7, the damper 104 may be provided in the space between the rear side substrate 24 of the photovoltaic module 100 and the surface of the support structure 30 at four positions that are point symmetrical with one another relative to the center of gravity C of the panel, rather than near the middle. Note that FIG. 6 is a plan view showing the photovoltaic module 100 mounted and viewed from the rear surface thereof. FIG. 7 is a cross sectional view along the line D-D in FIG. 6.

In particular, with the photovoltaic module 100 having the width W along the support structure 30, preferably, the damper 104 is provided in an area within a width W/4 from the central line L of the photovoltaic module 100.

With an arrangement in which the damper 104 is arranged point symmetrical relative to the center of gravity C of the panel of the photovoltaic module 100, as described above, point symmetrical flexure of the photovoltaic module 100 relative to the center of gravity C of the photovoltaic module 100, the flexure being caused with the fixing member 32 as a fulcrum, can be effectively reduced.

In addition, as shown in FIGS. 3 and 4, the damper 104 may be arranged filling the entire space. FIG. 3 is a plan view showing the photovoltaic module 100 mounted and viewed from the rear surface thereof. FIG. 4 is a cross sectional view along the line B-B in FIG. 3.

Preferably, the thickness of the damper 104 is substantially equal to the width of the space between the rear side substrate 24 of the photovoltaic module 100 and the surface of the support structure 30. That is, preferably, the thickness of the damper 104 is substantially equal to the thickness d of the bottom portion 32a of the fixing member 32. With the above, with the photovoltaic module 100 fixedly mounted on the mounting support structure 102, the photovoltaic module 100 can be maintained flat between the edge parts and the middle part thereof, so that a stress to be applied to the photovoltaic module 100 can be reduced.

The damper 104 may be adhered in advance in a desired position on the rear side substrate 24 of the photovoltaic module 100 or on the surface of the support structure 30. Alternatively, the damper 104 may be adhered in advance in both of the desired positions on the rear side substrate 24 of the photovoltaic module 100 and on the surface of the support structure 30. In the latter case, the thickness of the damper 104 may be defined such that the combined thickness of the respective dampers 104 becomes substantially equal to the width of the space caused between the rear side substrate 24 of the photovoltaic module 100 and the surface of the support structure 30. A method for adhering the damper 104 is not limited to those described above, and another method including one using an adhesive agent such as epoxy resin or the like may be available.

With an arrangement in which the damper 104 is adhered in advance to the photovoltaic module 100 or the support structure 30, as described above, required work, such as positioning or the like, in mounting the photovoltaic module 100 to the support structure 30 can be easily accomplished.

With the photovoltaic module 100 mounted on the mounting support structure 102, preferably, the respective dampers 104 are adhered on both of the rear side substrate 24 of the photovoltaic module 100 and the surface of the support structure 30. That is, with an arrangement in which the damper 104 is adhered on the front and rear surfaces thereof to the photovoltaic module 100 and the support structure 30, respectively, such that the photovoltaic module 100 is connected to the support structure 30 via the damper 104, the photovoltaic module 100 can be made less flexible even when the photovoltaic module 100 is exposed to a force, such as wind or the like, on the front surface side thereof, the force pushing the photovoltaic module 100 toward the support structure 30, or a force on the rear surface side, the force pulling the photovoltaic module 100 apart from the support structure 30. This can reduce damage on the photovoltaic module 100.

In particular, with the damper 104 arranged in a point symmetrical position relative to the center of gravity C of the panel, the position being apart from the middle of the panel, as shown in FIGS. 6 and 7, when the photovoltaic module 100 is exposed to a force on the rear surface side thereof, the force pulling the photovoltaic module 100 apart from the support structure 30, an increase in the distance between the photovoltaic module 100 and the support structure 30 due to the flexure is smaller, compared to a case with the damper 104 arranged near the middle. This can reduce the possibility of the damper 104 being removed from the photovoltaic module 100 or the support structure 30.

Preferably, the damper 104 is removable from at least one of the photovoltaic module 100 and the support structure 30. For example, the damper 104 is attached to at least one of the photovoltaic module 100 and the support structure 30, using a hook-and-loop fastener, so that the damper 104 can be removed. With this arrangement, should the photovoltaic module 100 need to be exchanged for any reason after being mounted on the mounting support structure 102, the photovoltaic module 100 can be readily removed from the mounting support structure 102.

Preferably, the damper 104 has a high reflecting rate for light in a wavelength area which can be absorbed in the photovoltaic module 100. For example, the damper 104 may be colored white. With this arrangement, the light having passed through the photovoltaic module 100 via the separating groove 22a is reflected by the damper 104 so that the light is introduced again to the photovoltaic cell 22, which can improve photovoltaic efficiency of the photovoltaic module 100.

What is claimed is:

1. An installation structure for installing a photovoltaic module comprises:
a photovoltaic panel;
a support structure for supporting the photovoltaic module mounted thereon;
a fixing member for fixing the photovoltaic module to the support structure; and
a damper placed between a rear surface of the photovoltaic module and a surface of the support structure when the photovoltaic module is fixed to the support structure, using the fixing member.

2. The installation method for installing a photovoltaic module according to claim 1, wherein the damper is positioned point symmetrical relative to a center of gravity of the photovoltaic module.

3. The installation method for installing a photovoltaic module according to claim 1, wherein the damper is adhered on the rear surface of the photovoltaic module and the surface of the support structure.

4. The installation method for installing a photovoltaic module according to claim 2, wherein the damper is adhered on the rear surface of the photovoltaic module and the surface of the support structure.

5. The installation method for installing a photovoltaic module according to claim 1, wherein the damper is removable from at least one of the photovoltaic module and the support structure.

6. The installation method for installing a photovoltaic module according to claim 2, wherein the damper is removable from at least one of the photovoltaic module and the support structure.

7. The installation method for installing a photovoltaic module according to claim 3, wherein the damper is removable from at least one of the photovoltaic module and the support structure.

8. The installation method for installing a photovoltaic module according to claim 1, wherein the support structure is arranged along a separating groove formed on the photovoltaic module.

9. A photovoltaic module comprising:
a photovoltaic panel;
a fixing member for fixing the photovoltaic module; and
a damper placed in a space that is caused between a rear surface of the photovoltaic module and a surface of a support structure for supporting the photovoltaic module mounted thereon when the fixing member is fixed to the support structure.

10. A mounting support structure for a photovoltaic module for carrying a photovoltaic module mounted thereon, the mounting support structure having a damper placed in a space that is caused between a rear surface of the photovoltaic module and the mounting support structure when a fixing member provided to the photovoltaic module is fixed.
